(19) United States
(12) Patent Application Publication
(10) Pub. No.: US 2012/0305044 A1
(43) Pub. Date: Dec. 6, 2012

(54) THERMAL TRANSFER AND POWER GENERATION SYSTEMS, DEVICES AND METHODS OF MAKING THE SAME

(76) Inventor: ANDREY A. ZYKIN, Getzville, NY (US)

(21) Appl. No.: 13/313,129

(22) Filed: Dec. 7, 2011

Related U.S. Application Data
(60) Provisional application No. 61/420,645, filed on Dec. 7, 2010.

(51) Int. Cl. H01L 35/30; F25B 21/02

(52) U.S. Cl. 136/201; 62/3.7; 136/205

(57) ABSTRACT

The invention relates to thermoelectric systems, devices and methods for generating energy and, providing cooling and heating. Non-ceramic thermoelectric technology is employed. In the invention, non-ceramic substrates are used to replace the ceramic layers which are typically utilized in conventional thermoelectric structures. The non-ceramic substrates can be selected from metals and metal-containing materials known in the art which have a surface modification, such as but not limited to, a coating or a surface restructuring. The incorporation of non-ceramic substrates allows several other components which are associated with the use of ceramic layers in conventional thermoelectric structures to be eliminated from the thermoelectric device.

### CROSS-REFERENCE TO RELATED APPLICATION

The present application is a traditional application of U.S. Provisional Patent Application 61/420,645, filed Dec. 7, 2010, and entitled “SYSTEMS AND METHODS FOR NON-CERAMIC THERMOELECTRIC ENERGY GENERATION, COOLING AND HEATING APPLICATIONS” which is herein incorporated by reference in its entirety.

### 1. FIELD OF THE INVENTION

The invention relates generally to heat transfer and power generation systems and devices, and more particularly, to solid state thermoelectric systems, devices and methods of making the same.

### 2. BACKGROUND

Thermoelectric systems and devices can be used for a variety of heating/cooling and power generation/heat recovery systems, such as refrigeration, air conditioning, electronics cooling, industrial temperature control, waste heat recovery and power generation. These systems and devices offer certain advantages, such as high reliability, reduced size and weight, reduced noise and low maintenance.

In a thermoelectric device, heat is transferred by the flow of electrons through pairs of p-type and n-type semiconductor thermoelements forming structures that are connected electrically in series and thermally in parallel.

The thermoelectric systems and devices which are known in the art typically include several heat exchangers connected with thermoelectric modules fixed between them. In general, a thermoelectric device forms a p-n junction pair by joining a p-type thermoelectric semiconductor and n-type thermoelectric semiconductor via a metal electrode. There is a temperature gradient in the p-n junction pair. A thermoelectric module is capable of converting thermal energy produced from the temperature gradient into electrical energy and therefore, the thermoelectric module can function as an electrical generator. This phenomenon is well-known as the “Seebeck effect”. The thermoelectric module is also capable of converting electrical energy into a temperature gradient. This phenomenon is well-known as the “Peltier effect”.

When power is applied from a battery or other power source to the thermoelectric module, heat will be moved through from one side of the module to the other side. As a result, one side of the module is made cold while the other (opposite) side simultaneously is made hot. The module will absorb heat on the “cold side” and eject it out the “hot side” to a heat sink. The heat sink is also capable of dissipating the electrical power applied to the module, which exits through the modules' “hot side”. Interestingly, if the polarity or current flow through the module is reversed, the “cold side” will become the “hot side” and vice versa. Thus, the thermoelectric module can be used for heating, cooling and temperature stabilization.

The thermoelectric modules are typically compressed between a heat sink and something to be cooled. The addition of a heat sink to a module creates a thermoelectric device. The object cooled can be selected from a wide variety of suitable objects, such as, a block of metal creating a cold plate, another forced convection heat sink making an air-to-air exchanger, a liquid heat sink forming a liquid-to-air exchanger, and a probe for a water cooler.

In general, thermoelectric modules are operated from a Direct Current (DC) power source. DC power sources can include DC power supplies, AS/DC converters, batteries and battery chargers.

Thermoelectric systems and devices which are known in the art typically consist of two or more elements of n- and p-type doped semiconductor material that are connected electrically in series and thermally in parallel. These thermoelectric elements and their electrical interconnects typically are mounted between two ceramic substrates. These ceramic substrates function to hold the overall structure together mechanically and to electrically insulate the individual elements from one another and from the external mounting surfaces.

There are disadvantages associated with known thermoelectric devices and systems, and the use of ceramic substrates within the thermoelectric modules. For example, many of the known thermoelectric devices are costly to produce and exhibit low efficiency, and therefore, the use of these devices is restricted to small scale applications.

Accordingly, there is a desire to provide a low cost, high efficiency thermoelectric device for heat transfer and power generation applications.

### SUMMARY OF THE INVENTION

In one aspect, the invention provides a system including a heat source, a heat sink, a first insulation layer associated with the heat source, the layer constructed of a non-ceramic substrate having a surface and a modification applied to the surface, a second insulation layer associated with the heat sink, the layer constructed of a non-ceramic substrate having a surface and a modification applied to the surface and a thermoelectric device positioned between the heat source and the heat sink, configured to provide heating or cooling or to generate power, the device including a plurality of p-type and n-type thermoelectric semiconductors positioned between the heat source and the heat sink, wherein pairs of the p-type and n-type thermoelectric semiconductors are connected by a component.

In another aspect, the invention provides a method to generate power, including providing a thermal energy source, a heat sink, a first insulation layer associated with the thermal energy source, the layer constructed of a non-ceramic substrate having a surface and a modification applied to the surface, a second insulation layer associated with the heat sink, the layer constructed of a non-ceramic substrate having a surface and a modification applied to the surface and a thermoelectric device positioned between the thermal energy source and the heat sink, configured to provide heating or cooling or to generate power, the device including a plurality of p-type and n-type thermoelectric semiconductors positioned between the thermal energy source and the heat sink, wherein pairs of the p-type and n-type thermoelectric semiconductors are connected by a component, connecting the thermal energy source to the thermoelectric device, passing thermal energy through the thermoelectric device, and converting the thermal energy to electrical energy.

In still another aspect, the invention provides a method for heating, cooling and stabilizing temperature, including providing an electrical energy source, a heat sink, a first insulation layer associated with the electrical energy source, the layer constructed of a non-ceramic substrate having a surface and a modification applied to the surface, a second insulation layer associated with the heat sink, the layer constructed of a non-ceramic substrate having a surface and a modification applied to the surface and a thermoelectric device positioned between the electrical energy source and the heat sink, configured to provide heating or cooling or to generate power, the device including a plurality of p-type and n-type thermoelectric semiconductors positioned between the electrical energy source and the heat sink, wherein pairs of the p-type and n-type thermoelectric semiconductors are connected by a component, connecting the electrical energy source to the thermoelectric device, passing electrical energy through the thermoelectric device; and converting the electrical energy to a temperature gradient.

### BRIEF DESCRIPTION OF THE DRAWINGS

A full understanding of the invention can be gained from the following description of the preferred embodiments when read in conjunction with the accompanying drawings in which:

FIG. 1 is a diagrammatical illustration of a system having a thermal transfer device in accordance with an embodiment of the invention;

FIG. 2 is a diagrammatical illustration of a system having a thermal transfer device in accordance with an embodiment of the invention;

FIG. 3 is a diagrammatical illustration of a power generation system having a thermal transfer device in accordance with an embodiment of the invention; and

### DETAILED DESCRIPTION OF THE INVENTION

The invention relates to thermoelectric systems, devices and methods for making the same. The thermoelectric systems and devices are useful for thermal transfer and power generation applications. These systems and devices are based on non-ceramic thermoelectric technology. These systems and devices typically include two substrates or components wherein heat is transferred from one substrate or component to the other substrate or component. In certain embodiments, the invention includes one or more heat sinks, one or more active structures and one or more sources of heat or energy (e.g., conductors). The heat sinks and sources of heat or energy have an insulation layer which includes of a non-ceramic substrate, such as a metal or metal alloy having a surface modification applied thereon. The surface modification is applied to a contact surface of the substrate and forms an insulation layer on the contact surface. The surface modification can include, but is not limited to, a coating, film or treatment being deposited or applied to the surface or a restructuring of the surface using various techniques known in the art.

The modification applied to the contact surface can form an insulation layer which is thermally conductive and electrically insulating.

In certain embodiments, the thermoelectric systems and devices of the invention differ from conventional thermoelectric systems and devices known in the art by substituting non-ceramic substrates or layers for ceramic layers.

Without being bound by any particular theory, it is believed that the use of non-ceramic material in thermoelectric systems provides at least one of the following benefits as compared to the use of ceramic material: (i) improved thermal conductivity, (ii) less thermal resistance, (iii) improved thermal transferability and (iv) lower cost of production.

The thermoelectric devices which are known in the art and which include ceramic material typically also include other layers, such as lapping pastes and contact pads. The thermoelectric devices of the invention are substantially simplified in comparison with the conventional thermoelectric structures. The thermoelectric devices in accordance with certain embodiments of the invention can exclude the several layers of lapping pastes and contact pads that are present in the conventional thermoelectric structures. For example, a conventional thermoelectric structure can include a cold side, ceramic pads as insulation layers, soldering pads, metallization, active structure, hot side, thermal paste and heat sink.

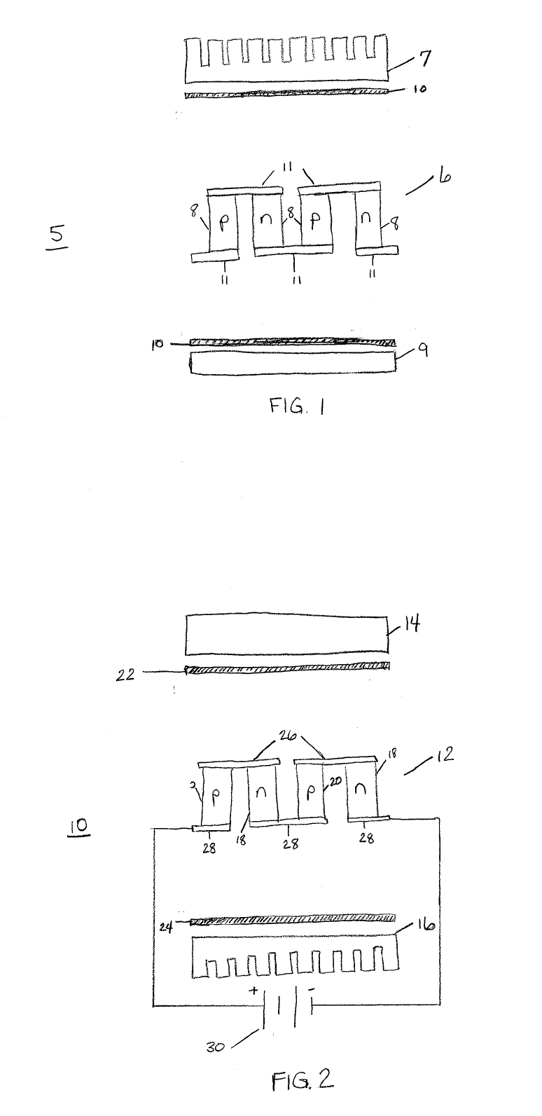

In certain embodiments of the invention, as shown in FIG. 1, a thermoelectric device 5 includes a heat sink 7, an active structure 6, a hot side 9 and layers 10, each of which consists of a non-ceramic substrate having a surface modification thereon. The active structure 6 includes a plurality of p-type and n-type thermoelectric semiconductor pairs 8 and a component 11 to form a junction between the p-type and n-type thermoelectric semiconductors. The active structure 6 can be free-floating such that it is mechanically loose from the heat sink 7 and the hot side 9.

In certain embodiments, the heat sink 7 and hot side 9 are disposed so as to be opposed to each other. Further, one layer 10 is associated with the heat sink 7 and another layer 10 is associated with the hot side 9 such that each of the layers 10 are also disposed so as to be opposed to each other. A plurality of p-type and n-type thermoelectric elements is alternatively arrayed between the heat sink 7 and the hot side 9. Further, the plurality of p-type and n-type thermoelectric elements is alternatively arrayed between the two layers 10. The p-type and n-type thermoelectric elements are connected by the component 11 which can consist of a layer between p-type and n-type pairs. In general, when electric current is supplied to one of the non-ceramic components, i.e., heat sink 7 and hot side 9, the temperature of one of them becomes lower and that of the other becomes higher.

In certain embodiments, the heat sink 7, active structure 6, layers 10 and hot side 9 are attached or fastened together to form the thermoelectric device. They can be attached or fastened using a wide variety of conventional means known in the art, such as, but not limited to, bolts or clips (not shown).

In one embodiment, the heat sink is an integral part of the thermoelectric device. In known thermoelectric structures it is typical for the heat sink to be a separate part which is simply attached to the thermoelectric device.

In certain embodiments, the invention includes a method for preparing new thermoelectric systems and devices which include the use of non-ceramic, modified substrates. In other embodiments, an existing conventional thermoelectric structure which has ceramic insulation layers can be modified by replacing the ceramic insulation layers with non-ceramic insulation layers, such as, metal or metal alloy sheets and plates having a surface modification applied thereon. This can be a direct replacement such that the size and shape of the new metal or metal alloy sheets and plates are the same as the existing ceramic ones.

FIG. 2 shows a system 10 including a thermal transfer module 12. The thermal transfer module 12 transfers heat from a first area or first object 14 to a second area or second object 16. The second object 16 may function as a heat sink for dissipating the transferred heat. Thermal transfer module 12 may be used for generating power to provide heating or cooling of the first and second objects 14 and 16, respectively. Further, first and second objects 14 and 16, respectively, may generate low-grade heat or high-grade heat. The first and second objects 14 and 16, respectively, may be components of a wide variety of articles including, but not limited to, a vehicle, turbine, aircraft engine, solid oxide fuel cell, refrigeration system and the like.

Positioned between the first and second objects 14 and 16, respectively, are a first layer 22 associated with the first object 14 and a second layer 24 associated with the second object 16, each of which includes a non-ceramic substrate having a surface modification applied on the contact surface. The thermoelectric module 12 includes n-type semiconductor legs 18 and p-type semiconductor legs 20 that function as thermoelements, whereby heat generated by charge transport is transferred away from the first object 14 towards the second object 16. In this embodiment, the n-type and p-type semiconductor legs 18 and 20, respectively, are each disposed on a first component 26 and a second component 28 to electrically connect pairs of n-type and p-type semiconductor legs 18 and 20, respectively. The first component 26, the second component 28 and the n-type and p-type semiconductor legs 18 and 20, respectively, are positioned between the first object 14 and the second object 16. Further, the first component 26, the second component 28 and the n-type and p-type semiconductor legs 18 and 20, respectively, are positioned between the first layer 22 and the second layer 24.

In this embodiment, the n-type and p-type semiconductor legs 18 and 20 are coupled electrically in series and thermally in parallel. In certain embodiments, a plurality of pairs of n-type and p-type semiconductors 18 and 20 may be used to form thermocouples that are connected electrically in series and thermally in parallel for facilitating heat transfer. In operation, an input voltage source 30 provides a flow of current through the n-type and p-type semiconductors 18 and 20, respectively. The thermoelectric module 12 facilitates heat transfer away from the first object 14 towards the second object 16.

In certain embodiments, the polarity of the input voltage source 30 in the system 10 may be reversed to enable the charge carriers to flow in the reverse or opposite direction, e.g., from the second object 16 to the first object 14. Thus, heating the first object 14 and causing the first object 14 to function as a heat sink. As described above, the thermoelectric module 12 may be employed for heating or cooling of the first and second objects 14 and 16, respectively.

Further, the thermoelectric module 12 may be employed for heating or cooling objects in a variety of applications, such as air conditioning and refrigeration systems, an aircraft engine, a vehicle, or a turbine and the like. In certain embodiments, the thermoelectric device 12 may be employed for power generation by maintaining a temperature gradient between the first and second objects 14 and 16, respectively.

In certain embodiments of the invention, the plurality of pairs of n-type and p-type semiconductors 18 and can be connected to the first object 14 and the second object 16 and the first layer 22 and the second layer 24.

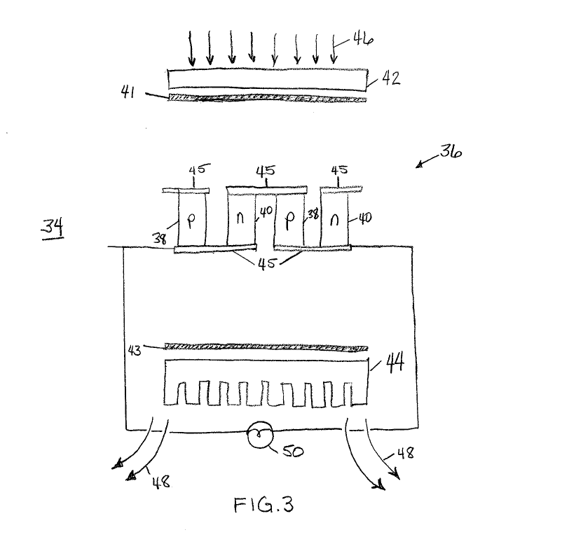

FIG. 3 illustrates a power generation system 34 having a thermal transfer device 36 in accordance with an embodiment of the invention. The thermal transfer device 36 includes p-type legs 38 and n-type legs 40 configured to generate power by maintaining a temperature gradient between a first object 42 and a second object 44. Positioned between the first and second objects 42 and 44, respectively, are a first layer 41 and a second layer 43, respectively, each of which includes a non-ceramic substrate having a surface modification applied on the contact surface. The p-type and n-type legs 38 and 40, respectively, are coupled electrically by component 45. In operation, heat is pumped into the first object 42 as represented by reference numeral 46 and is emitted from the second object 44 as represented by reference numeral 48. As a result, an electrical voltage 50 proportional to a temperature gradient between the first object 42 and the second object 44 is generated due to the Seebeck effect that may be further utilized to power a variety of applications. Examples of such applications include, but are not limited to, use in a vehicle, a turbine and an aircraft engine. Additionally, such thermoelectric devices may be coupled to photovoltaic or solid oxide fuel cells that generate heat including low-grade heat and high-grade heat thereby boosting overall system efficiencies.

It will be recognized by one having ordinary skill in the art that a plurality of thermocouples having the p-type and n-type legs 38 and 40, respectively, may be employed based upon a desired power generation capacity of the power generation system 34. Further, the plurality of thermocouples may be coupled electrically in series, for use in certain applications.

In certain embodiments, the insulation layer includes a non-ceramic substrate having a surface modification applied thereon. The non-ceramic substrate can include metal or metal-containing material known in the art, such as but not limited to, aluminum, aluminum alloy, magnesium, magnesium alloy, titanium, titanium alloy and mixtures thereof. The contact surface of the hot and cold (heat) sinks is modified. The surface modification can include deposition of a coating or film on the surface or treating or restructuring the surface. The coating, film, treatment or restructuring to be applied is selected such that it has an electrical insulation effect sufficient to allow the thermoelectric device to exert its functions and is capable of being applied and adhered to the surface of the substrate.

In certain embodiments of the invention, the insulation layer can be connected, adjacent or coupled to the heat sink and/or heat or energy source. In certain other embodiments, the insulation layer can be integrated with the heat sink and/or the heat or energy source.

The surface modification can be produced using various conventional methods known in the art. Non-limiting examples of conventional techniques and methods include, but are not limited to, micro arc oxidation (MAO), cathodic arc low temperature separated ion deposition (CALT SID), ion beam deposition, cold plasma ion deposition, separated cold plasma deposition, atmospheric plasma spraying (APS), vacuum plasma spraying (VPS), low-pressure plasma spraying (LPPS), controlled-atmosphere plasma spraying (CAPS), inert plasma spraying (IPS), shrouded plasma spraying (SPS), physical sputtering, electronic sputtering, potential sputtering, ionic plasma deposition (IPD) and various other methods known for depositing or growing materials and substances on top or inside insulate(ing) heat/cold conductors (layers), such as heat sinks, cold sinks, sheets of alloys, alloys and metals.

In one embodiment, micro plasma arch oxidation is used to restructure and coat a surface of the non-ceramic (e.g., metal or metal alloy) substrate. Generally, micro plasma arch oxidation can be used to restructure and coat a substrate made of metal or metal alloy, such as, for example, aluminum, titanium and the like. A coating on the surface of the substrate is produced due to oxidation of the metal substrate. The coating forms and grows due to the inclusion of electrolyte elements into its composition. The electrolyte elements enter the coating in the form of salts, oxides and hydroxides. The length of the treatment relates to the accumulation on the surface, e.g., the longer the length of the treatment, the greater the accumulation of elements from the electrolyte in the surface layer. Typically, the lower layer of the coating (i.e., the portion of the coating near to or adjacent the metal or metal alloy substrate) consists, mainly, of its oxide compounds. Most of the element inside of the coating composition is aluminum oxide which has improved mechanical properties as compared to aluminum.

In certain embodiments, the coating, film, treatment or restructured surface forms a non-ceramic, insulation layer.

The p-type and n-type thermoelectric semiconductors are typically made of materials, such as bismuth-tellurium (Bi—Te)-type materials, iron-silicon (Fe—Si)-type materials, silicon-germanium (Si—Ge)-type materials, and cobalt-antimony (Co—Sb)-type materials.

Without being bound by any particular theory, it is believed that the thermoelectric devices in accordance with certain embodiments of the invention exhibit at least one of the following benefits: (i) improved cooling performance and generation efficiency from about 15% to about 30% (as compared to conventional, e.g., ceramic substrate, thermoelectric structures) due to less heat-transfer resistance and heat flow losses, which can significantly improve the performance and efficiency of these devices incorporating the thermoelectric technology of the present invention; (ii) high reliability due to minimizing technical risks because systems incorporating the thermoelectric technology developed in accordance with the invention can withstand from about 5 to about 10 times more thermal cycles (switching on/off); (iii) minimal strains between the individual components of a system of the invention due to rapid and/or considerable temperature drops; (iv) improved resistance to mechanical impacts due to lack of ceramic laminas that are fragile components of conventional thermoelectric systems which can be damaged as a result of mechanical impacts and vibration; (v) application in industries wherein conventional thermoelectric systems could not be used, such as, but not limited to, motor-vehicle construction, civil engineering and manufacturing of road machines; (vi) prolonged effective lifespan based on the improvement of device parameters as contacts lapping as a result of thermo-cycling; (vii) stable operational parameters maintained during the entire period of operation whereas conventional thermoelectric systems can show progressive fatigue as contact breakdown occurs; (viii) cost effectiveness and reduced operating expenses because of the reduction of inter-lamina contact resistance (3 to 5 times) based on the consumption of thermoelectric material; (ix) reduction in maintenance and service; (x) unique, low, heat-transfer resistance because the thermoelectric systems of the invention do not contain ceramic substrates, thermal gaskets and thermal pastes which are used for lapping and providing additional heat resistance in conventional thermoelectric systems; (xi) ease of installation and assembling because the non-ceramic thermoelectric systems of the invention can be built into a device with the use of screw fastening, welding operation and the like without the use of specific intricate systems intended for the removal of heat flow and expensive thermal pastes; (xii) significant reduction in installation and service maintenance of up to five times and (xiii) an opportunity to produce elements of any shape and configuration due to the use of aluminum or other metal alloys technology.

The thermoelectric devices in accordance with certain embodiments of the invention can be used in a wide variety of applications. For example, in cooling and heat setting applications, the thermoelectric devices can be used in the following industries: electronics, optics and photonics, telecommunications, medicine and construction (residential and commercial). For power generation applications, the thermoelectric devices can be used in the following industries: micro-generation for autonomous sensor operation, mid-level generation for independent operation of different types of equipment (including hot water heaters, vehicles and the like), generators used for securing uninterrupted electrical equipment operation (e.g., computers, engines, boilers) and micro generators for sensors and transducers. Particularly, in generation systems utilizing waste heat from cars, vehicles, boilers, glass plants, painting facilities, chemical plants. The thermoelectric devices are also useful as generators in geothermal heat utilization.

As previously described, the thermoelectric devices in accordance with certain embodiments of the invention include the use of non-ceramic substrates, e.g., metal or metal alloy, instead of conventional ceramic layers. The surfaces of the substrates have a coating, a film, treatment or are re-structured by methods known in the art to produce improved mechanical and electrical properties. In addition, the coating, film, treatment or restructuring can result in the surface being slick. The slickness property can be obtained with little or minimal polishing.

Additional features of the thermoelectric systems in accordance with certain embodiments of the invention can include substantially-higher efficiency of cooling, thermo-stabilizing and heat output; potential to embed thermoelectric elements (e.g., an active structure including bismuth-telluride or other materials) into the body of end product which may include thermoelectric modules, thermoelectric systems and thermoelectric devices; simplicity of mounting and installation; potential to bear mechanical exposures; and longer operation life.

In certain embodiments of the invention, the thermoelectric devices can include sliding semiconductors inside the thermo-element structure (e.g., an active structure including bismuth-telluride or other materials) which can contribute to a larger range of delta T and higher working temperatures (up to about 360° C.). Further, insulation heat/cold conductors (layers) can be applied on top of heat sinks, cold sides of thermoelectric systems (e.g., thermoelectric modules, devices, units, etc.) to allow improved technical and other parameters, such as, reduction in thermal resistance, improved performance, and improved efficiency of the thermoelectric systems. Furthermore, the thermoelectric devices in accordance with certain embodiments of the invention can have one or more of the following attributes: the ability to take apart a thermoelectric unit to fix or replace the active structure and assemble back together, for example, the manufacturer can assemble in about 5 to about 10 minutes, instead of several hours; the integration of the thermo element (active structure bismuth telluride or other materials) and the end product (e.g., thermoelectric module, system, device); and the ability for any shape to be formed on/in a wide variety of metal surfaces, such as, but not limited to aluminum and aluminum alloys.

Further, certain embodiments of the invention provide for simplicity of mounting as follows:

Ability to attach (e.g., bolt, screw, clip or the like) the thermo-element (e.g., active structure including bismuth-telluride or other materials) on or in-between the heat/cold sinks;

Lapping is not required in the final assembly;

Polishing is not required in the final assembly;

Thermal paste is not required in the final assembly; and

Lapping tolerance is not required.

Moreover, certain embodiments of the invention provide for new efficiency standards, such as the following:

A broader extended range of temperatures;

The thermoelectric structure can be frozen without any substantial harm—due to icing to structure and/or of thermo-element (e.g., active structure containing bismuth-telluride or other materials); and

Ability to withstand mechanical exposures, such as but not limited to, vibration, dropping, shaking, hitting and the like.

While the invention has been described in terms of various specific embodiments, those skilled in the art will recognize that the invention can be practiced with modifications within the spirit and scope of the appended claims.

1. A system, comprising:
a heat source;
a heat sink;
a first insulation layer associated with the heat source, the layer constructed of a non-ceramic substrate having a surface and a modification applied to the surface;
a second insulation layer associated with the heat sink, the layer constructed of a non-ceramic substrate having a surface and a modification applied to the surface; and
a thermoelectric device positioned between the heat source and the heat sink and configured to provided heating or cooling or to generate power, the device comprising a plurality of p-type and n-type thermoelectric semiconductors positioned between the heat source and the heat sink, wherein pairs of the p-type and n-type thermoelectric semiconductors are connected by a component.

2. The system of claim 1, wherein the non-ceramic substrate is constructed of a material selected from the group consisting of a metal and a metal alloy.

3. The system of claim 2, wherein the substrate of each of the first and second insulation layers is constructed of the same material.

4. The system of claim 2, wherein the substrate of each of the first and second insulation layers is constructed of a different material.

5. The system of claim 2, wherein the metal is selected from the group consisting of aluminum, magnesium, titanium and mixtures thereof.

6. The system of claim 2, wherein the metal alloy is selected from the group consisting of aluminum alloy, magnesium alloy, titanium alloy and mixtures thereof.

7. The system of claim 1, wherein each of the p-type and n-type thermoelectric semiconductors are constructed of a material selected from the group consisting of bismuth, tellurium, iron, silicon, germanium, cobalt, antimony or a mixture thereof.

8. The system of claim 7, wherein the p-type and n-type thermoelectric semiconductors are constructed of a material selected from the group consisting of bismuth-tellurium, iron-silicon, silicon-germanium, cobalt-antimony and mixtures thereof.

9. The system of claim 1, wherein there is an absence of thermal paste and soldering pads.

10. The system of claim 1, wherein the modification applied to the surface is selected from the group consisting of depositing a coating or film on the surface, treating the surface and re-structuring the surface.

11. The system of claim 10, wherein the surface modification is achieved by a technique selected from the group consisting of micro arc oxidation, cathodic arc low temperature separated ion deposition and ionic plasma deposition.

12. The system of claim 1, wherein the plurality of p-type and n-type thermoelectric semiconductors are positioned between the first insulation layer and the second insulation layer.

13. A method to generate power, comprising:
providing a thermal energy source;
providing a heat sink;
a first insulation layer associated with the thermal energy source, the layer constructed of a non-ceramic substrate having a surface and a modification applied to the surface;
a second insulation layer associated with the heat sink, the layer constructed of a non-ceramic substrate having a surface and a modification applied to the surface; and
providing a thermoelectric device positioned between the thermal energy source and the heat sink and configured to generate power, the device comprising a plurality of p-type and n-type thermoelectric semiconductors positioned between the thermal energy source and the heat sink, wherein pairs of the p-type and n-type thermoelectric semiconductors are connected by a component;
connecting the thermal energy source to the thermoelectric device;
passing thermal energy through the thermoelectric device; and
converting the thermal energy to electrical energy.

14. The system of claim 13, wherein each of the first and second non-ceramic substrates is constructed of a material selected from the group consisting of a metal and a metal alloy.

15. The system of claim 13, wherein the plurality of p-type and n-type thermoelectric semiconductors are positioned between the first insulation layer and the second insulation layer.

16. The system of claim 13, wherein the modification applied to the surface is selected from the group consisting of depositing a coating or film on the surface, treating the surface and re-structuring the surface.

17. A method for heating, cooling and stabilizing temperature, comprising:
providing an electrical energy source;
providing a heat sink;
a first insulation layer associated with the electrical energy source, the layer constructed of a non-ceramic substrate having a surface and a modification applied to the surface;
a second insulation layer associated with the heat sink, the layer constructed of a non-ceramic substrate having a surface and a modification applied to the surface; and
providing a thermoelectric device positioned between the electrical energy source and the heat sink, the device comprising a plurality of p-type and n-type thermoelectric semiconductors positioned between the electrical energy source and the heat sink, wherein pairs of the p-type and n-type thermoelectric semiconductors are connected by a component;
connecting the electrical energy source to the thermoelectric device;
passing electrical energy through the thermoelectric device; and
converting the electrical energy to a temperature gradient.

18. The system of claim 17, wherein each of the first and second non-ceramic substrates is constructed of a material selected from the group consisting of a metal and a metal alloy.

19. The system of claim 17, wherein the plurality of p-type and n-type thermoelectric semiconductors are positioned between the first insulation layer and the second insulation layer.

20. The system of claim 17, wherein the modification applied to the surface is selected from the group consisting of depositing a coating or film on the surface, treating the surface and re-structuring the surface.
